(19) United States
(12) Patent Application Publication
(10) Pub. No.: US 2007/0241830 A1
(43) Pub. Date: Oct. 18, 2007

(54) Surface mount crystal oscillator and method of manufacturing same

(75) Inventor: Hidenori Harima, Saitama (JP)

Correspondence Address: KATTEN MUCHIN ROSENMAN LLP, 575 MADISON AVENUE, NEW YORK, NY, 10022-2585, US

(73) Assignee: Nihon Dempa Kogyo Co., LTD.

(21) Appl. No.: 11/731,100

(22) Filed: Mar. 30, 2007

(30) Foreign Application Priority Data
Mar. 31, 2006 (JP) 2006-098898

(51) Int. Cl. H03B 5/32

(52) U.S. Cl. 331/158

(57) ABSTRACT

A surface mount crystal oscillator comprises: a crystal unit having a crystal blank hermetically sealed in a package, and first external terminals formed on an outer bottom surface of the package; and a mounting substrate for containing an IC chip which has an oscillation circuit integrated therein, the oscillation circuit using the crystal blank. The mounting substrate includes second external terminals corresponding to the first external terminals on one main surface, and mounting terminals on the other main surface. The mounting substrate comprises a printed wiring board made up of a lower layer, an intermediate frame layer having an opening, and an upper layer laminated one on another. The IC chip is placed in a hollow space defined by the opening. The first external terminals are bonded to the second external terminals to integrate the crystal unit with the mounting substrate.

### BACKGROUND OF THE INVENTION

1. Field of the Invention

The present invention relates to a crystal oscillator of a surface mount type in which a quartz crystal unit and an IC (Integrated Circuit) chip having an oscillation circuit using the crystal unit are integrated as a single assembly. More particularly, the present invention relates to a small bonding type surface mount crystal oscillator which is constituted by bonding a crystal unit to a mounting substrate mounted with an IC chip and in which the connection strength between the crystal unit and the mounting substrate is increased to improve productivity. The present invention also relates to a method of manufacturing the surface mount crystal oscillator.

2. Description of the Related Arts

Surface mount crystal oscillators are built particularly in portable electronic devices, for example, mobile telephones, as reference sources for frequency and time because of their small sizes and light weights. One type of such a surface mount crystal oscillator is a bonding type surface mount crystal oscillator as shown in Japanese Patent Laid-open Application No. 2003-87056 (JP-A-2003-087056). The bonding type surface mount crystal oscillator is fabricated by accommodating an IC chip and a crystal blank in separate packages, respectively, and subsequently bonding these packages for integration.

FIG. 1A illustrates an exemplary configuration of a conventional bonding type surface mount crystal oscillator, and FIG. 1 B illustrates a mounting substrate which functions as a package for containing an IC chip.

The illustrated surface mount crystal oscillator comprises crystal unit 3 and mounting substrate 2 which contains IC chip, and mounting substrate 2 is bonded to the bottom surface of crystal unit 3. Mounting substrate 2, which has a substantially rectangular geometry, is formed with a recess in one main surface thereof for accommodating IC chip 1. Mounting substrate 2 is made of laminated ceramics. At four corners on one main surface of mounting substrate 2, i.e., at four corners on an open end surface surrounding the recess, external terminals 5 are formed for electrically and mechanically bonding mounting substrate 2 to the bottom surface of crystal unit 3. At four corners of the other main surface of mounting substrate 2, i.e., the outer bottom surface of mounting substrate 2, mounting terminals 4 are disposed for use in surface-mounting the crystal oscillator onto a wiring board.

IC chip 1 has electronic circuits integrated on a semiconductor substrate. The electronic circuits include an oscillation circuit which uses crystal unit 3, and a temperature compensation mechanism for compensating crystal unit 3 for frequency-temperature characteristics. The oscillation circuit and temperature compensation mechanism are formed on one main surface of the semiconductor substrate by a general semiconductor device fabricating process. Accordingly, a circuit forming surface will herein refer to one of the two main surfaces of IC chip 1 on which the oscillation circuit and temperature compensation mechanism are formed on the semiconductor substrate. A plurality of IC terminals are also formed on the circuit forming surface for connecting IC chip 1 to external circuits. The IC terminals include a power supply terminal, a ground terminal, an oscillation output terminal, and a pair of connection terminals for connection with the crystal unit.

Circuit terminals are disposed on the bottom surface of the recess in mounting substrate 2 in correspondence to the IC terminals. Circuit terminals corresponding to the power supply terminal, ground terminal, and oscillation output terminal of IC chip 1 are electrically connected to mounting terminals 4 through conductive paths, not shown, respectively. Circuit terminals corresponding to the pair of connection terminal of IC chip 1 are electrically connected to external terminals 5, for example, located at both ends of one diagonal of the mounting substrate 2, through conductive paths, not shown. The remaining two of external terminals 5 are electrically connected to the ground terminal within mounting terminals 4, for example, through through-holes extended through mounting substrate 2. IC chip 1 is secured to the bottom surface of mounting substrate 2 by electrically and mechanically connecting the IC terminals to the circuit terminals through ultrasonic thermo-compression bonding using bumps 6 such that the circuit forming surface faces the bottom surface of the recess in mounting substrate 2. Then, protection resin layer 16 is disposed within the recess of mounting substrate 2 as a so-called under-fill to fill in a crevice between the bottom surface of the recess and circuit forming surface of IC chip 1 for purposes of protecting the circuit forming surface.

For reference, mounting substrate 2 is formed by laminating ceramic green sheets (i.e., unburned sheets of ceramic material) each having a size corresponding to a plurality of mounting substrates 2 to create a laminate, burning the laminate, and subsequently cutting the burned laminate into individual mounting substrates 2. The laminate has been formed with a plurality of recesses, each of which corresponds to the recess of mounting substrate 2, at a stage before the burning.

Crystal unit 3 in turn comprises crystal blank 8 contained in recessed package body 7 which is made of laminated ceramics, and metal cover 9 bonded to an open end surface surrounding the recess to hermetically seal crystal blank 8 within the recess. In this event, metal cover 9 is bonded to a metal thick film or metal ring 20 disposed on the open end surface through seam welding or beam welding. At four corners on the outer bottom surface of package body 7, external terminals 10 are disposed in correspondence to external terminals 5 on mounting substrate 2. A pair of crystal holding terminals 12 are disposed on the bottom surface of the recess in package body 7 for holding crystal blank 8.

As illustrated in FIG. 2, crystal blank 8, which comprises, for example, a substantially rectangular AT-cut quartz crystal blank, is provided with excitation electrodes 11a on both main surfaces, respectively. From these excitation electrodes 11a, lead-out electrodes 11b are extended toward both ends of one side of crystal blank 8, respectively. Crystal blank 8 is secured to crystal holding terminals 12 with conductive adhesive 13 or the like at both ends of the one side thereof toward which lead-out electrodes 11b are extended, whereby crystal blank 8 is electrically and mechanically connected to crystal holding terminals 12, and held within the recess of package body 7.

In package body 7, a pair of crystal holding terminals 12 are electrically connected to a pair of external terminals 10, which are positioned on one diagonal on the outer bottom surface of package body 7, through conductive paths, not shown. External terminals 10 positioned on the other diagonal on the outer bottom surface of package body 7 are electrically connected to metal cover 9 through via holes or the like extended through package body 7.

Then, external terminals 5 of mounting substrate 2 are connected to external terminals 10 of crystal unit 3 using soldering or the like to electrically and mechanically connect mounting substrate 2 with crystal unit 3, thereby completing a crystal oscillator. In this event, crystal holding terminals 12 in crystal unit 3 are electrically connected to the IC terminals through external terminals 10, external terminal 5, and circuit terminals, causing crystal blank 8 to electrically connect to the oscillation circuit within IC chip 1. Likewise, metal cover 9 is also electrically connected to the ground terminal within mounting terminals 4.

The bonding type crystal oscillator is fabricated by independently forming mounting substrate 2 mounted with IC chip and crystal unit 3, and then bonding both components. If a defect is found, for example, in the crystal unit itself, the defective crystal unit can be discarded before it is bonded to mounting substrate 2, to avoid consuming expensive IC chips for nothing. Consequently, the bonding type crystal oscillator lends itself to improving the productivity.

However, the surface mount crystal oscillator configured as described above implies problems as described below, due to the fact that mounting substrate 2 is made of laminated ceramics which are brittle material. Specifically, the laminated ceramics which are brittle material inferior in mechanical workability, and experience difficulties particularly in cutting and division. For this reason, when the aforementioned laminate of ceramic green sheets having a plurality of recesses is burned and then divided into individual mounting substrates 2, a portion of the laminated ceramics tends to partially chip. Accordingly, such damaged (i.e., chipped) mounting substrates are removed such that IC chips 1a re placed only in acceptable mounting substrates 2. In this way, expensive IC chips are prevented from wasteful use. Of course, if a burned ceramic laminate is cut with extra care, damages and the like can be reduced in the laminated ceramics, in which case, however, the productivity will be significantly degraded.

Mounting substrates 2, which have IC chips 2 contained therein, are each bonded to the bottom surface of crystal unit 3. Here, mounting substrate 2 is coated with creamed solder on external terminals 5 which are aligned to external terminals 10 of crystal unit 3. Then, these components are carried into a pass-through type furnace, and bonded to each other by reflow soldering. In this event, the creamed solder must be coated individually onto respective external terminals 5 on mounting substrate 2 by a dispenser or the like, while confirming the positions of external terminals 5. This coating process causes a lower productivity, as compared with a printing approach or the like by which the creamed solder can be coated.

As crystal oscillators are increasingly reduced in size to an extent that the outside planar dimensions are reduced, for example, to 2.5 mm×2.5 mm, the area of each external terminal 5 disposed on the open end surface of mounting substrate 2 is also reduced to cause a reduction in the strength with which crystal unit 3 is bonded to mounting substrate 2. If the recess in mounting substrate 2 is reduced with respect to the outside dimensions, external terminals 5 can be increased in size to provide an improved bonding strength, in which case, however, the recess for receiving IC chip 1 therein is reduced in area, causing difficulties in placing a relatively large IC chip which has, for example, a temperature compensation mechanism integrated therein.

To solve the problems described above, it is contemplated that a flat side of mounting substrate 2 is bonded to crystal unit 3, such that the recessed side is mounted on a wiring board. In this assembly, crystal unit 3 can be bonded to mounting substrate 2 with a higher strength, but mounting terminals 4 formed on the open end surface surrounding the recess cannot be increased in size, resulting in a lower strength of connection between the crystal oscillator and the wiring board on which the crystal oscillator is mounted.

Therefore, irrespective of whether the recess in mounting substrate 2 faces the crystal oscillator or circuit board, the problems still remain unsolved in regard to the inability to increase the external terminals or mounting terminals in size due to the formation of the opening of the recess on mounting substrate 2 to result in a lower bonding strength.

Japanese Patent Laid-open Application No. Hei-8-172315 (JP-A-8-172315) discloses a method of manufacturing a crystal oscillator which includes the steps of: placing a cylindrical crystal unit in each of a plurality of recesses formed in a printed wiring board; mounting IC chips and discrete parts on the printed wiring board for connection to the respective crystal units; and subsequently dividing the printed wiring board into individual crystal oscillators. Here, measurement terminals are disposed along one side of the printed wiring board, and the measuring terminals are electrically connected to the IC chips through a circuit pattern routed on the printed wiring board, such that each crystal oscillator is tested for oscillation characteristics, followed by cutting/division of the printed wiring board to provide individual crystal oscillators while eliminating defective items. Even if the manufacturing method described in JP-A-8-172315 is applied to the conventional bonding type surface mount crystal oscillator illustrated in FIGS. 1A and 1B, the printed wiring board in the manufacturing method of JP-A-8-172315 is replaced with laminated ceramics which are brittle material, resulting in higher susceptibility to damages of laminated ceramics when the laminate is divided into individual crystal oscillators, and even lower productivity.

### SUMMARY OF THE INVENTION

It is an object of the present invention to provide a surface mount crystal oscillator which is conducive to a higher bonding strength between a mounting substrate and a crystal unit, higher suitability for a reduction in size, and higher productivity.

It is another object of the present invention to provide a method of a surface mount crystal oscillator which is conducive to a higher bonding strength between a mounting substrate and a crystal unit, higher suitability to a reduction in size, and higher productivity.

The first object of the present invention is achieved by a surface mount crystal oscillator which comprises: a crystal unit having a crystal blank hermetically sealed in a package, and first external terminals formed on an outer bottom surface of the package; and a mounting substrate for containing an IC chip which has an oscillation circuit, using the crystal unit, integrated therein, and including second external terminals corresponding to the first external terminals on one main surface, and mounting terminals on the other main surface. In this surface mount crystal oscillator, the mounting substrate comprises a printed wiring board made up of a lower layer, an intermediate frame layer, and an upper layer laminated one on another, the intermediate frame layer has an opening, the opening defines a hollow space sandwiched by the lower layer and the upper layer, the IC chip is placed in the hollow space, and the first external terminals are bonded to the second external terminals to integrate the crystal unit with the mounting substrate.

In this crystal oscillator, the first external terminals and second external terminals may be bonded to each other by soldering using the creamed solder, and the creamed solder may be coated on the first external terminals and/or second external terminals by a printing method. With the foregoing configuration, since the mounting substrate is implemented by a printed wiring board, individual crystal oscillators can be created by using a mounting substrate sheet corresponding to a plurality of mounting substrates, and cutting or dividing the mounting substrate sheet into individual mounting substrates, thus improving the productivity. Also, since both main surfaces of the mounting substrate are flat, the creamed solder can be readily printed. In addition, the second external terminals and mounting terminals can be increased in size, as compared with the conventional ones. As a result, the crystal oscillator and mounting substrate, as well as the mounting substrate and wiring board can be bonded with higher bonding strengths.

In the crystal oscillator of the present invention, both crystal unit and mounting substrate have a substantially rectangular planar outer shape, the first external terminals may be formed at four corners on an outer bottom surface of the package, the second external terminals are formed at four corners on the one main surface of the mounting substrate, and the mounting terminals may be formed at four corners on the other main surface of the mounting substrate. Such a crystal oscillator may be manufactured by, for example, a manufacturing method comprising: using a mounting substrate sheet having a plurality of hollow spaces corresponding to a plurality of the mounting substrates, the mounting substrate sheet being made up of the lower layer, intermediate frame layer, and upper layer which are commonly provided for the plurality of mounting substrates, the IC chip being contained in each of the hollow spaces, the mounting substrate sheet having measurement terminals electrically connected to the IC chips along at least one edge thereof; coating creamed solder by printing on the second external terminals formed on each area which is to serve as the each mounting substrate on the mounting substrate sheet; collectively mounting the crystal units such that the first external terminals are in alignment to the second external terminals in each the area, and bonding the crystal units to the mounting substrate sheet with the melted creamed solder to create a plurality of oscillators; testing each oscillator for oscillation characteristics through the measurement terminals; and dividing, after the test, the mounting substrate sheet into the respective areas so as to separate the mounting substrate sheet into individual mounting substrates.

In this manufacturing method, the creamed solder can be coated by a printing method, and the mounting substrate sheet can be readily cut or divided after individual oscillators have been tested. Accordingly, the productivity can be improved in manufacturing the surface mount crystal oscillator.

### BRIEF DESCRIPTION OF THE DRAWINGS

FIG. 1A is a cross-sectional view illustrating the exemplary configuration of a conventional surface mount crystal oscillator;

FIG. 1B is a plan view illustrating a mounting substrate used in the crystal oscillator illustrated in FIG. 1A;

FIG. 2 is a plan view of a crystal blank;

FIG. 3 is a cross-sectional view illustrating another exemplary configuration of a conventional surface mount crystal oscillator;

FIG. 4 is a cross-sectional view illustrating the configuration of a surface mount crystal oscillator according to one embodiment of the present invention;

FIG. 5A is a plan view illustrating a mounting substrate sheet; and

FIG. 5B is a partial cross-sectional view of the mounting substrate sheet when crystal units are mounted thereon.

### DETAILED DESCRIPTION OF THE PREFERRED EMBODIMENTS

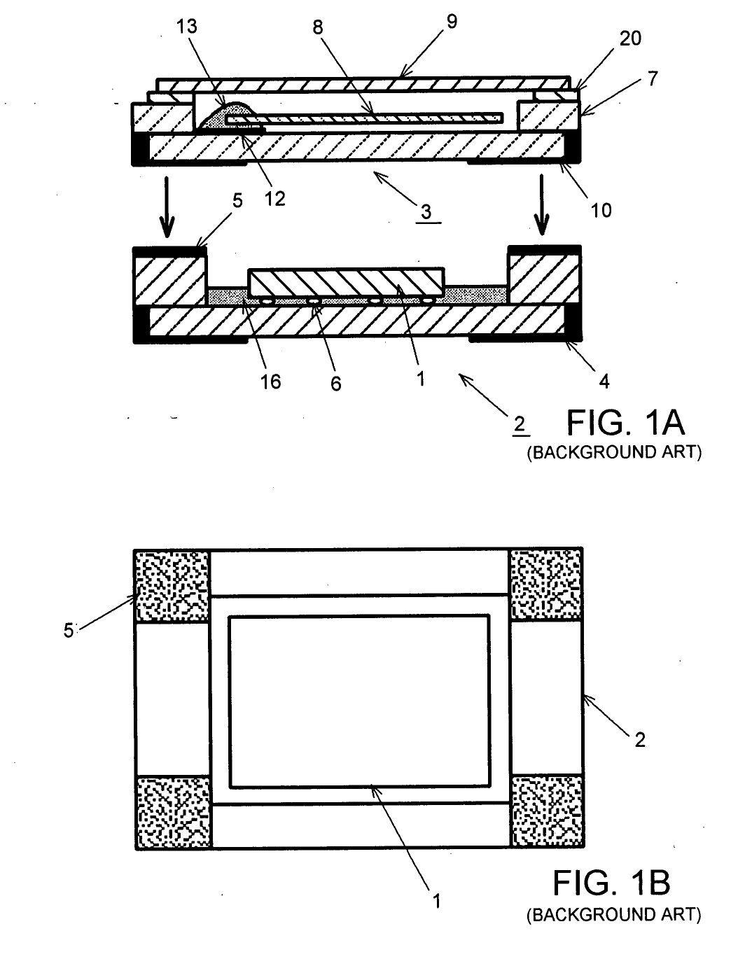

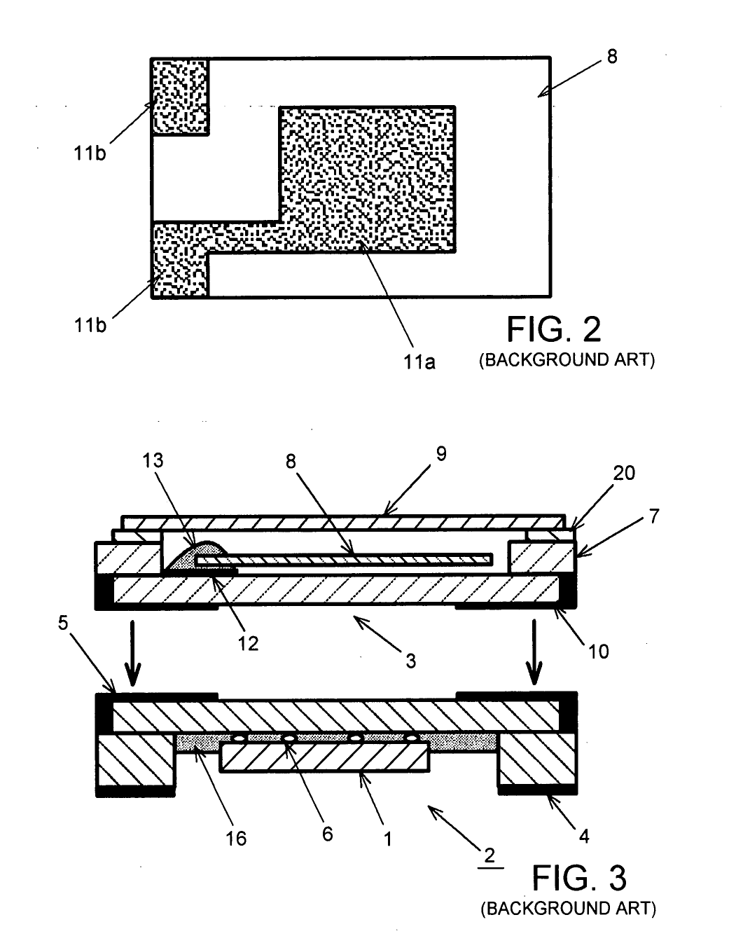

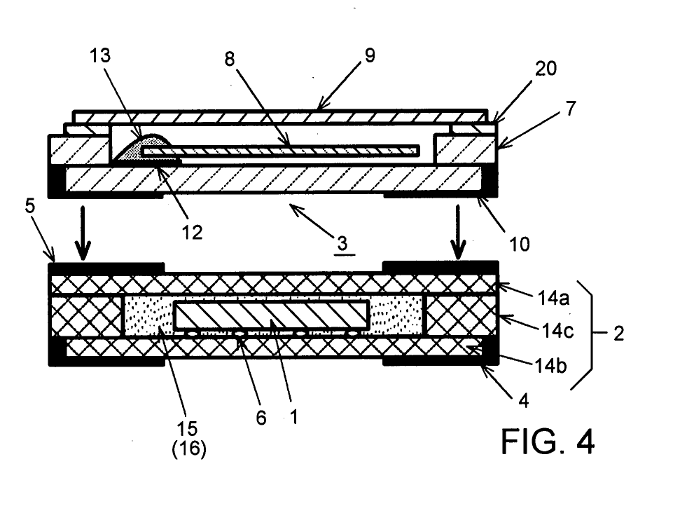

In FIG. 4 which illustrates a surface mount crystal oscillator according to one embodiment of the present invention, the same components as those in FIGS. 1A and 1B are designated the same reference numerals, and repeated descriptions will be omitted.

The surface mount crystal oscillator illustrated in FIG. 4 comprises quartz crystal unit 3 and mounting substrate 2 which contains IC chip 1, and mounting substrate 2 is bonded to the bottom surface of crystal unit 3, as described above. Crystal unit 3 used herein is the same as the one described in connection with FIGS. 1A and 1B. Likewise, IC chip 1 used herein is similar to the one described above.

Mounting substrate 2 comprises a printed wiring board which has a substantially rectangular outer planar shape and uses a glass epoxy material as a base material. Specifically, mounting substrate 3 is made up of three sheets made of glass epoxy material in a trilaminar structure in which intermediate frame layer 14c is sandwiched between upper layer 14a and lower layer 14b. Each of upper layer 14a and lower layer 14b is formed flat, while intermediate frame layer 14a is formed with an opening which is completely sandwiched by upper layer 14a and lower layer 14b. The opening is therefore isolated from the outside to define hollow space 15. As will be later described, IC chip 1 is placed within hollow space 15.

Wiring patterns are formed on the surfaces of upper layer 14a, lower layer 14b, and intermediate frame layer 14c. The wiring patterns are formed by disposing copper foil over the entire surfaces of corresponding layers 14a to 14c, and patterning the copper foil into desired shapes by etching.

At four corners on one main surface of mounting substrate 2, i.e., the outer surface of upper layer 14a, external terminals 5 are formed for use in electrically and mechanically connecting with crystal unit 3. External terminals 5 are formed on the outer surface of substantially rectangular upper layer 14a to extend from the respective four corners to positions located above hollow space 15. In other words, external terminals 5 are formed to jut over hollow space 15 across upper layer 14a. At four corners on the other main surface of mounting substrate 2, i.e., the outer surface of lower layer 14b, mounting terminals 4 are disposed for use in surface-mounting the crystal oscillator onto a wiring board of a device in which the crystal oscillator is to be mounted. Like external terminals 5, mounting terminals 4 are also formed to extend to positions below hollow space 15 across lower layer 14b.

A plurality of circuit terminals are disposed in correspondence to the IC terminals of IC chip 1 at sites on the surface of lower layer 14b which face hollow space 15. The circuit terminals are electrically connected to mounting terminals 4 and external terminals 5 through the aforementioned circuit patterns, and via holes extended through respective layers 14a to 14c. Then, IC chip 1 is secured to the surface of lower layer 14b within hollow space 15 by electrically and mechanically bonding the IC terminals to the circuit terminals through ultrasonic thermo-compression bonding which involves bumps 6. Also, in this bonding process, electronic circuits within IC chip are electrically connected to mounting terminals 4 and external terminals 5.

Such mounting substrate 2 is formed by a known multi-layer wiring board formation technology. Upper layer 14a and intermediate frame layer 14c, as well as lower layer 14b and intermediate frame layer 14c are adhered to each other with the same resin 16 as that used in the glass epoxy material, i.e., prepreg on their respective laminated surfaces. Then, this resin 16 is also filled in hollow space 15 in which IC chip 1 is placed, such that IC chip 1 is adhered to lower layer 14 with a higher strength by the action of resin.

Mounting substrate 2 thus configured is electrically and mechanically bonded to crystal unit 3 by soldering external terminals 5 of mounting substrate 2 to external terminals 10 of crystal unit 3. This soldering causes the previously coated creamed solder to melt. Here, the creamed solder is coated on external terminals 5 formed on one main surface of mounting substrate 5, i.e., on the surface of upper layer 14a, by printing, and subsequently, crystal unit 3 is placed on mounting substrate 2. The resulting assembly is carried into a high-temperature pass-through type furnace for reflow soldering.

By bonding mounting substrate 2 to the bottom surface of crystal unit 3, crystal blank 8 within crystal unit 3 is electrically connected to the oscillation circuit within IC chip 1 to complete a crystal oscillator, as is the case with the aforementioned conventional crystal oscillator.

As described above, in the surface mount crystal oscillator of this embodiment, mounting substrate 2 is made of a glass epoxy material in a trilaminar structure, which is apt to cutting operations, hollow space 15 is defined in intermediate frame layer 14c sandwiched between upper layer 14a and lower layer 14b, and IC chip 1 is contained within this hollow space 15. In this event, hollow space 15 is isolated from external air by upper layer 14a and lower layer 14b. This crystal oscillator lends itself to improving the productivity because it can be manufactured by a manufacturing method which includes bonding crystal units onto a plurality of mounting substrates 2 defined on a single substrate sheet, and dividing the sheet into individual crystal oscillators. Also, since both main surfaces of mounting substrate 2 are flat, external terminals 5 of mounting substrate 2 can be readily bonded to external terminals 10 of crystal unit 3 using creamed solder which is coated by a printing method.

In this crystal oscillator, since external terminals 5 and mounting terminals 4 on mounting substrate 2 are all formed to extend from the four corners on mounting substrate 2 to positions over hollow space 15, external terminals 5 and mounting terminals 4 can be formed to have larger areas than those in the conventional crystal oscillator illustrated in FIGS. 1A and 1B. Accordingly, even if the crystal oscillator is reduced in size, a high bonding strength can be maintained between mounting substrate 2 and crystal unit 3, and a high bonding strength can also be maintained between mounting substrate 2 and wiring board. Since the external terminals and mounting terminals are not disposed at four corners on the surface of intermediate frame layer 14c, the opening, i.e., hollow space 15 in intermediate frame layer 14c can be increased in area, allowing mounting substrate 2 to receive relatively large IC chip 1, which may contain a temperature compensation mechanism. Therefore, according to this embodiment, the surface mount crystal oscillator lends itself to facilitating a reduction in size.

Next, a description will be given of a method of manufacturing the crystal oscillator. Generally, this method employs a mounting substrate sheet corresponding to a plurality of crystal oscillators, and includes collectively bonding a plurality of crystal units to the mounting substrate sheet, and subsequently cutting or dividing the mounting substrate sheet into individual mounting substrates with respective crystal oscillators, thereby producing a plurality of crystal oscillators at a time.

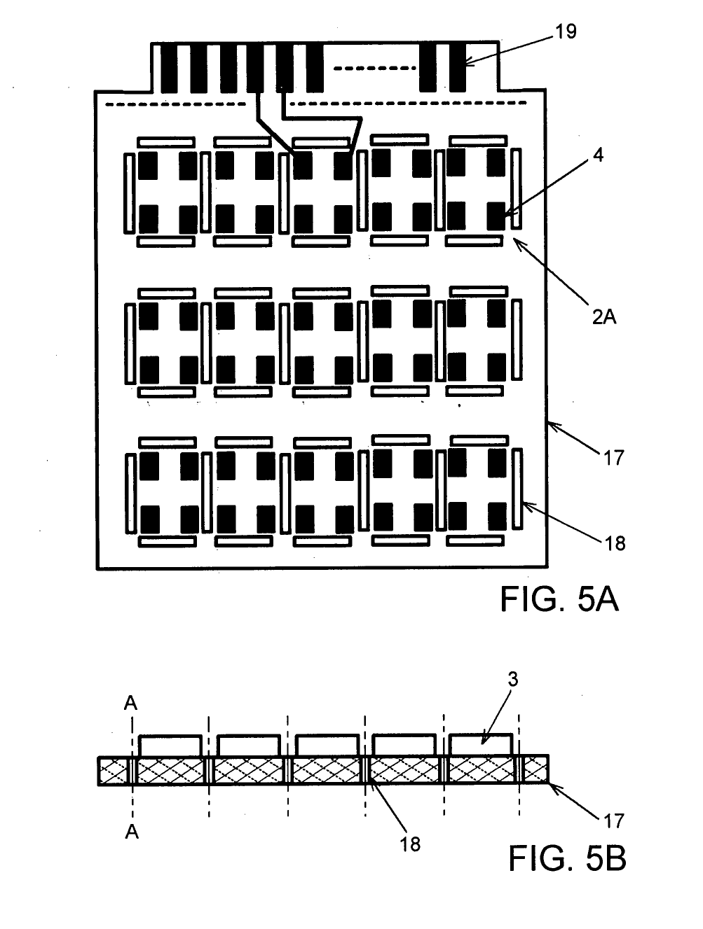

FIG. 5A is a bottom view of a mounting substrate sheet used herein. Mounting substrate sheet 17 is a printed wiring board which comprises a plurality of the aforementioned mounting substrates arranged in the horizontal and vertical directions, and contains IC chip 1 in each of areas which are to be assembled into crystal oscillators. Then, individual crystal oscillators are completed through a first to a fourth step described below.

First, mounting substrate sheet 17 will be described. Like the one illustrated in FIG. 4, mounting substrate sheet 17 is made of a glass epoxy material and has a trilaminar structure made up of upper layer 14a, intermediate frame layer 14c, and lower layer 14b which are laminated one on another. An area corresponding to the mounting substrate for each crystal oscillator cut from mounting substrate sheet 17 is called “mounting substrate portion” 2A. Accordingly, mounting substrate sheet 17 has mounting substrate portions 2A arranged in the vertical and horizontal directions. Then, division grooves 18 are drawn on mounting substrate sheet 17 along four sides of the periphery of each mounting substrate portion 2A for facilitating the division of mounting substrate sheet 17. Division grooves 18 may extend through both main surfaces of mounting substrate sheet 17, or formed in the shape of linear recess on the surface of mounting substrate sheet 17.

For each mounting substrate portion 2A, hollow space 15 is formed through intermediate frame layer 14c, and IC chip 1 has been previously embedded within hollow space 15 in a manner similar to the foregoing. For each mounting substrate portion 2A, upper layer 14a and lower layer 14b are formed flat. IC chip 1 comprises IC terminals, similar to those described above, which include a power supply terminal, a ground terminal, an oscillation output terminal, a pair of connection terminals for connection to a crystal unit, and the like. Also, in each mounting substrate portion 2A, external terminals 5 are formed at four corners on the surface of upper layer 14a, and mounting terminals 4 are formed at four corners on the surface of lower layer 14b. Among the IC terminals, the power supply terminal, ground terminal, oscillation output terminals and the like are electrically connected to mounting terminals 4. In each mounting substrate portion 2A, external terminals 5 located at both ends of one diagonal are electrically connected to the connection terminals within the IC terminals of IC chip 1, while the remaining two of external terminals 5 are connected to the ground terminal within mounting terminals 4.

A plurality of measurement terminals 19 are arranged in a row along one edge of mounting substrate sheet 17. These measurement terminals 19 are electrically connected to mounting terminals 4 of each mounting substrate portion 2A through wiring paths, i.e., a wiring pattern formed on mounting substrate sheet 17.

Next, a description will be given of a process of assembling surface mount crystal oscillators using the foregoing mounting substrata sheet 17. It is assumed that a plurality of crystal units which have the same structure as described above are previously prepared.

First, in a first step, a mask is applied to the surface of upper layer 14a in mounting substrate sheet 17, such that external terminals 5 alone expose on each mounting substrate portion 2A, and creamed solder is collectively coat on external terminals 5 by printing.

Next, in a second step, respective crystal units 3 are mounted on respective mounting substrate portions 2A such that external terminals 10 of crystal units 3 are aligned to external terminals 5 of mounting substrate portions 2A. Mounting substrate sheet 17 mounted with the crystal units are carried into a high-temperature pass-through type furnace to melt the creamed solder, thereby electrically and mechanically bonding external terminals 5 of mounting substrate 17 to external terminals 10 of crystal units 3. In this way, a plurality of crystal units 3 are bonded to mounting substrate sheet 17, as illustrated in a cross-sectional view of FIG. 5B, to form a plurality of crystal oscillators on mounting substrate sheet 17.

Next, each of the crystal oscillators formed on mounting substrate sheet 17 in the second step is tested for oscillation characteristics in a third step. The test for oscillation characteristics is conducted by connecting mounting substrate sheet 17 to a measuring instrument, not shown, through measuring terminals 19 which are formed to serve as connectors in a row along one edge of mounting substrate sheet 17, and measuring electric characteristics such as oscillation frequency for each crystal oscillator. Subsequently, in a fourth step, mounting substrate sheet 17 is cut along division grooves 18, for example, by a dicing saw for separation of respective mounting substrate portions 2A from one another, thereby dividing mounting substrate sheet 17 into individual mounting substrates 2. Line A-A in FIG. 5B indicates an exemplary cutting position.

With the manufacturing method as described above, both main surfaces of mounting substrate sheet 17 are flat except for the division grooves, so that the creamed solder can be coated on external terminals 5 formed on the surface of mounting substrate sheet 17 by a printing method. Therefore, the step for coating the creamed solder can be facilitated, as compared with a conventional coating step which involves coating creamed solder using a dispenser. Also, since this manufacturing method collectively bonds a plurality of crystal units 3 onto mounting substrate sheet 17 to create a plurality of crystal oscillators, integrally tests each oscillator for oscillation characteristics through measurement terminals 19, and eventually divides mounting substrate sheet 17 into individual crystal oscillators, the productivity can be improved in the manufacturing of the surface mount crystal oscillators.

In the respective embodiments described above, a glass epoxy material is used as a base material for making the printed wiring boards which constitute mounting substrate 2 and mounting substrate sheet 17, but the present invention is not limited to this particular material. Any arbitrary printed wiring board can be used for mounting substrate 2 and mounting substrate sheet 17 if it is formed with a wiring pattern on a laminate made up of an insulating material and metal foil adhered thereto.

What is claimed is:

1. A surface mount crystal oscillator comprising:
crystal unit having a crystal blank hermetically sealed in a package, and first external terminals formed on an outer bottom surface of the package; and
mounting substrate for containing an IC chip which has an oscillation circuit integrated therein, said oscillation circuit using said crystal unit, said mounting substrate including second external terminals corresponding to the first external terminals on one main surface, and mounting terminals on the other main surface,
wherein said mounting substrate comprises a printed wiring board made up of a lower layer, an intermediate frame layer, and an upper layer laminated one on another, said intermediate frame layer having an opening, said opening defining a hollow space sandwiched by said lower layer and said upper layer, said IC chip being contained in said hollow space, and
said first external terminals are bonded to said second external terminals to integrate said crystal unit with said mounting substrate.

2. The crystal oscillator according to claim 1, wherein said first external terminals and said second external terminals are bonded to each other by soldering using creamed solder.

3. The crystal oscillator according to claim 2, wherein said creamed solder is coated on said first external terminals and/or said second external terminals by a printing method.

4. The crystal oscillator according to claim 1, wherein both said crystal unit and said package body have a substantially rectangular planar geometry, said first external terminals are formed at four corners on an outer bottom surface of said package, said second external terminals are formed at four corners on the one main surface of said mounting substrate, and said mounting terminals are formed at four corners on the other main surface of said mounting substrate.

5. The crystal oscillator according to claim 5, wherein said first external terminals are formed to extend from the four corners on the one main surface to positions above said hollow space, and said mounting terminals are formed to extend from the four corners on the other main surface to positions below said hollow space.

6. The crystal oscillator according to claim 1, wherein said printed wiring board is a printed wiring board which uses a glass epoxy material as a base material.

7. A method of manufacturing the crystal oscillator according to claim 4, comprising:
using a mounting substrate sheet having a plurality of hollow spaces corresponding to a plurality of said mounting substrates, said mounting substrate sheet being made up of the lower layer, intermediate frame layer, and upper layer which are commonly provided for said plurality of mounting substrates, said IC chip being contained in each of the hollow spaces, said mounting substrate sheet having measurement terminals electrically connected to the IC chips along at least one edge thereof;
coating creamed solder by printing on the second external terminals formed on each area which is to serve as said each mounting substrate on said mounting substrate sheet;
collectively mounting said crystal units such that the first external terminals are in alignment to the second external terminals in each said area, and bonding said crystal units to said mounting substrate sheet with the melted creamed solder to create a plurality of oscillators;
testing each oscillator for oscillation characteristics through the measurement terminals; and
dividing, after the test, said mounting substrate sheet into the respective areas so as to separate said mounting substrate sheet into individual mounting substrates.
